(19) United States
(12) Patent Application Publication
(10) Pub. No.: US 2025/0038080 A1
(43) Pub. Date: Jan. 30, 2025

(54) SEMICONDUCTOR PACKAGE

(71) Applicant: Samsung Electronics Co., Ltd., Suwon-si (KR)

(72) Inventor: Eunsu Lee, Suwon-si (KR)

(21) Appl. No.: 18/675,558

(22) Filed: May 28, 2024

(30) Foreign Application Priority Data
Jul. 27, 2023 (KR) 10-2023-0098362

(51) Int. Cl. H01L 23/498; H01L 23/00; H01L 23/31; H01L 25/18; H10B 80/00

(52) U.S. Cl. CPC H01L 23/49811; H01L 23/31; H01L 23/49838; H10B 80/00; H01L 23/49833; H01L 24/16; H01L 25/18; H01L 2224/16145; H01L 2224/16225; H01L 2924/1431

(57) ABSTRACT

Provided is a semiconductor package including a first substrate, a first semiconductor package on the first substrate and including a first semiconductor chip, and a second semiconductor package on the first substrate spaced apart from the first semiconductor package in a horizontal direction, and including one or more semiconductor chips and a molding layer on the one or more semiconductor chips, wherein the molding layer includes a molding member and one or more dummy posts extending into the molding member in a vertical direction and configured to be electrically insulated.

### CROSS-REFERENCE TO RELATED APPLICATION

This application is based on and claims priority under 35 U.S.C. § 119 to Korean Patent Application No. 10-2023-0098362, filed on Jul. 27, 2023, in the Korean Intellectual Property Office, the disclosure of which is incorporated by reference herein in its entirety.

### BACKGROUND

The present inventive concept relates to a semiconductor package.

In the recent market of electronic appliances, demands for portable devices have been rapidly increasing, and as such, electronic components mounted on electronic appliances are continuously desired to be miniaturized and light in weight. For electronic components to be miniaturized and light in weight, semiconductor packages mounted on electronic components are required to process high-capacity data while reducing the volume thereof. Accordingly, a semiconductor package including a plurality of semiconductor chips is desired. For example, various kinds of semiconductor chips may be mounted on one package substrate side-by-side, or semiconductor chips or semiconductor packages may be stacked on one package substrate.

### SUMMARY

The inventive concept provides a semiconductor package including a side-by-side memory package and a logic package, wherein the logic package includes dummy posts.

It will be appreciated by one of ordinary skill in the art that that the objectives and effects that could be achieved with the inventive concept are not limited to what has been particularly described above and other objectives of the inventive concept will be more clearly understood from the following detailed description.

According to some embodiments, there is provided a semiconductor package including a first substrate, a first semiconductor package on the first substrate and including a first semiconductor chip, and a second semiconductor package on the first substrate spaced apart from the first semiconductor package in a horizontal direction, and including one or more semiconductor chips p and a molding layer on the one or more semiconductor chips, wherein the molding layer includes a molding member and one or more dummy posts extending into the molding member in a vertical direction and configured to be electrically insulated.

According to some embodiments, provided is a semiconductor package including a first substrate, a first semiconductor package on the first substrate and including a first semiconductor chip, and a second semiconductor package on the first substrate spaced apart from the first semiconductor package in a horizontal direction, and including one or more semiconductor chips and a molding layer on the one or more semiconductor chips, an underfill material layer between the second semiconductor package and the first substrate, and a dam structure protruding on the first substrate in a vertical direction and having a side wall at least partially contacting the underfill material layer, wherein the molding layer includes a molding member and one or more dummy posts extending into the molding member in a vertical direction and configured to be electrically insulated.

According to some embodiments, there is provided a semiconductor package including a first substrate, a first semiconductor package on the first substrate and including a first semiconductor chip, and a second semiconductor package comprising a second substrate, a lower semiconductor chip on the second substrate, an upper semiconductor chip on the lower semiconductor chip, and a molding layer on the lower semiconductor chip and the upper semiconductor chip, and on the first substrate spaced apart from the first semiconductor package in a horizontal direction, an underfill material layer between the second semiconductor package and the first substrate, and a dam structure protruding on the first substrate in a vertical direction and having a side wall at least partially contacting the underfill material layer, wherein the molding layer includes a molding member on the second substrate, and one or more dummy posts that are along a perimeter of the upper semiconductor chip and the lower semiconductor chip by passing through the molding member in a vertical direction and are configured to be electrically insulated.

### BRIEF DESCRIPTION OF THE DRAWINGS

Embodiments of the inventive concept will be more clearly understood from the following detailed description taken in conjunction with the accompanying drawings in which:

FIG. 1 is a plan view schematically showing a semiconductor package according to some embodiments;

FIG. 2 is a cross-sectional view taken along line I-I′ of FIG. 1;

FIG. 3 is an enlarged cross-sectional view of part EX1 in FIG. 2;

FIG. 4 is a plan view schematically showing a semiconductor package according to some embodiments;

FIG. 5 is a cross-sectional view taken along line II-II′ of FIG. 4;

FIG. 6 is a plan view schematically showing a semiconductor package according to some embodiments;

FIG. 7 is a cross-sectional view taken along line III-III′ of FIG. 6; and

FIGS. 8 to 12 are cross-sectional views schematically illustrating a method of manufacturing a semiconductor package, according to some embodiments.

### DETAILED DESCRIPTION OF THE EMBODIMENTS

Hereinafter, one or more embodiments of the inventive concept will be described in detail with reference to accompanying drawings. Like reference numerals denote the same elements on the drawings, and detailed descriptions thereof are omitted.

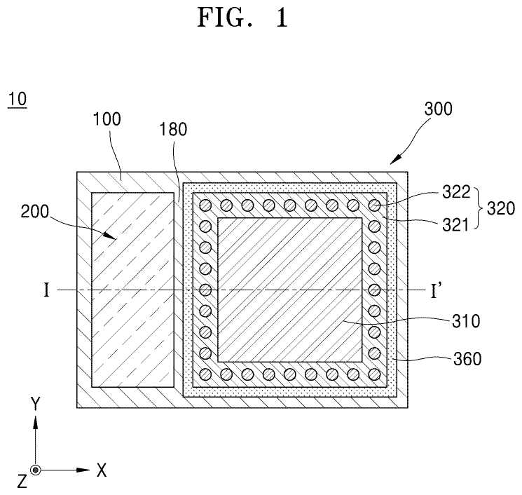

FIG. 1 is a plan view schematically showing a semiconductor package 10 according to some embodiments.

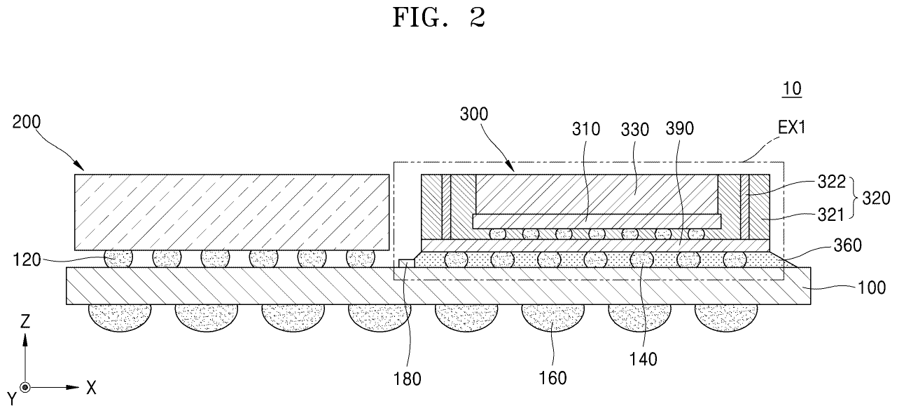

FIG. 2 is a cross-sectional view taken along line I-I′ of FIG. 1.

Referring to FIGS. 1 and 2, the semiconductor package 10 according to some embodiments may include a first substrate 100, a first semiconductor package 200, and a second semiconductor package 300. The first substrate 100 may be a substrate on which the first semiconductor package 200 and the second semiconductor package 300 are mounted. However, one or more embodiments are not limited thereto, and the first substrate 100 may be a substrate on which one or more semiconductor chips, in addition to the first semiconductor package 200 and the second semiconductor package 300, may be mounted. Also, a semiconductor chip may be mounted on the first substrate 100 in the form of a memory chip. For example, a single memory chip, instead of the first semiconductor package 200, may be mounted.

The first substrate 100 may include, for example, a ceramic substrate, a printed circuit board (PCB), an organic substrate, an interposer substrate, etc. Also, in some embodiments, the first substrate 100 may include a redistribution structure.

Hereinafter, in the drawings, an X-axis direction and a Y-axis direction denote directions parallel to the upper surface of the first substrate 100, and the X-axis direction and the Y-axis direction may be perpendicular to each other. The Z-axis direction may denote a direction perpendicular to the upper or lower surface of the first substrate 100. In other words, the Z-axis direction may be perpendicular to an X-Y plane.

Also, in the drawings, a first horizontal direction may be understood as the X-axis direction, the second horizontal direction may be understood as the Y-axis direction, and a vertical direction may be understood as the Z-axis direction.

The first semiconductor package 200 may be mounted on the upper surface of the first substrate 100. In some embodiments, a plurality of first semiconductor packages 200 may be provided and may be spaced apart from one another in a row on the upper surface of the first substrate 100 in the horizontal direction (X-axis direction and/or Y-axis direction).

In some embodiments, the first semiconductor package 200 may be on the upper surface of the first substrate 100. For example, the first semiconductor package 200 may be mounted on the first substrate 100 in a flip-chip bonding method via first bumps 120. Although not shown in FIG. 2, in some embodiments, an underfill material layer on the first bumps 120 (e.g., on sidewalls of the first bumps 120 or surrounding the first bumps 120) may be between the first semiconductor package 200 and the first substrate 100. However, one or more embodiments are not limited thereto, and the first semiconductor package 200 may be attached onto the first substrate 100 via a die attach film and may be electrically connected to the first substrate 100 via distribution wires, etc.

According to some embodiments, the first semiconductor package 200 may include one or more semiconductor chips. For example, the semiconductor chip is a memory chip and may include, for example, a volatile memory chip such as dynamic random-access memory (DRAM) or static RAM (SRAM), or a non-volatile memory chip such as phase-change RAM (PRAM), magnetoresistive RAM (MRAM), ferroelectric RAM (FeRAM), or resistive RAM (RRAM). However, one or more embodiments are not limited thereto, and the semiconductor chip may include a micro-processor such as a central processing unit (CPU), a graphics processing unit (GPU), or an application processor (AP), an analog element, or a logic chip such as a digital signal processor.

The second semiconductor package 300 may be mounted on the upper surface of the first substrate 100. The second semiconductor package 300 may be configured with the first semiconductor package 200 side-by-side. The second semiconductor package 300 may be on the first substrate 100 spaced apart from the first semiconductor package 200 in a first horizontal direction (X-axis direction). According to some embodiments, a plurality of second semiconductor packages 300 may be provided and may be spaced apart from one another in the horizontal direction (X-axis direction and/or Y-axis direction). For example, the plurality of second semiconductor packages 300 are configured spaced apart from one another in the second horizontal direction (Y-axis direction) and may be respectively spaced apart from the plurality of first semiconductor packages 200 in the first horizontal direction (X-axis direction).

The second semiconductor package 300 may be mounted on the first substrate 100 in a flip-chip bonding method via second bumps 140. Here, an underfill material layer 360 on (e.g., on sidewalls of or surrounding) the second bumps 140 may be formed between the second semiconductor package 300 and the first substrate 100. The underfill material layer 360 may include, for example, an epoxy resin formed by a capillary under-fill method. The underfill material layer 360 may be formed to have a tapered shape of which an area gradually increases downward between the second semiconductor package 300 and the first substrate 100 but is not limited thereto.

According to some embodiments, the second semiconductor package 300 may include one or more semiconductor chips which may include a logic chip. The logic chip may include a micro-processor such as a CPU, a GPU, and an AP, an analog element, or a digital signal processor. However, the embodiment is not limited thereto, and the semiconductor chip may include a volatile memory chip such as DRAM and SRAM, or a non-volatile memory such as PRAM, MRAM, FeRAM, and RRAM.

In some embodiments, the second semiconductor package 300 may include a second substrate 390, a lower semiconductor chip 310, an upper semiconductor chip 330, and a molding layer 320. The lower semiconductor chip 310 and the upper semiconductor chip 330 may be mounted on the upper surface of the second substrate 390.

In some embodiments, a planar area (X-Y plane) of the second substrate 390 may be greater than that of the lower semiconductor chip 310 and the upper semiconductor chip 330. That is, the second semiconductor package 300 may be of a fan-out type but is not limited thereto.

In some embodiments, the second substrate 390 may include a redistribution structure. However, the embodiment is not limited thereto, and the second substrate 390 may include a ceramic substrate, a PCB, an organic substrate, an interposer substrate, etc.

In some embodiments, the molding layer 320 may be on or surround the lower semiconductor chip 310 and the upper semiconductor chip 330. The molding layer 320 may include a molding member 321 and one or more dummy posts 322. The molding member 321 is on or surrounds the lower semiconductor chip 310 and the upper semiconductor chip 330, and the dummy posts 322 may pass through the molding member 321 in the vertical direction (Z-axis direction).

One or more dummy posts 322 are spaced apart from each other and may surround (e.g., be spaced apart around or along a perimeter of) the lower semiconductor chip 310 and the upper semiconductor chip 330. One or more dummy posts 322 may be spaced apart from each other in the horizontal direction (X-axis direction and/or Y-axis direction). One or more dummy posts 322 may be spaced apart from each other at a constant interval but are not limited thereto, that is, the dummy posts 322 may be irregularly arranged. For example, a plurality of dummy posts 322 may be configured in a row in the first horizontal direction (X-axis direction) and the second horizontal direction (Y-axis direction) on the second substrate 390, except for the region where the lower and upper semiconductor chips 310 and 330 are mounted. A pair of dummy posts 322 may be positioned in the first horizontal direction (X-axis direction) and the second horizontal direction (Y-axis direction) with the lower and upper semiconductor chips 310 and 330 therebetween.

In some embodiments, the dummy posts 322 may each have a cylinder shape and may have a diameter of 10 μm or greater. However, shapes of the dummy posts 322 are not limited thereto and, for example, may be a hexahedral shape.

The one or more dummy posts 322 may be formed to be electrically insulated from one another. For example, the one or more dummy posts 322 may be electrically insulated from the lower semiconductor chip 310, the upper semiconductor chip 330, and the second bumps 140. Here, the dummy posts 322 may include copper (Cu), aluminum (Al), tungsten (W), silver (Ag), gold (Au), or a combination thereof.

The second bumps 140 may be mounted on the lower surface of the second substrate 390. According to some embodiments, the second pump 140 may have a less volume than that of the first bump 120 but is not limited thereto.

The first substrate 100 may include a dam structure 180 protruding from the upper surface thereof in the vertical direction (Z-axis direction). The dam structure 180 may be between the first semiconductor package 200 and the second semiconductor package 300. The dam structure 180 may lengthily extend in the second horizontal direction (Y-axis direction) between the first semiconductor package 200 and the second semiconductor package 300. The dam structure 180 may be in contact with the underfill material layer 360 between the first substrate 100 and the second semiconductor package 300. For example, a side wall of the dam structure 180 may at least partially come into contact with the underfill material layer 360.

According to some embodiments, the underfill material layer 360 may be formed when an underfill material is introduced between the first substrate 100 and the second semiconductor package 300 and hardened. Here, the underfill material may be restricted from flowing due to the dam structure 180. Therefore, the dam structure 180 may prevent the underfill material layer 360 from being formed between the first semiconductor package 200 and the first substrate 100.

External connection terminals 160 may be on the lower surface of the first substrate 100. The external connection terminals 160 may be electrically connected to an external connection device via pads formed on the lower surface of the first substrate 100. The external connection device may include, for example, a motherboard, PCB, etc., or may include a package substrate. In some embodiments, the external connection terminal 160 may be formed of a solder ball. Also, in some embodiments, the external connection terminal 160 may have a structure including a pillar and solder. The external connection terminal 160 may include at least one of copper (Cu), silver (Ag), gold (Au), and tin (Sb).

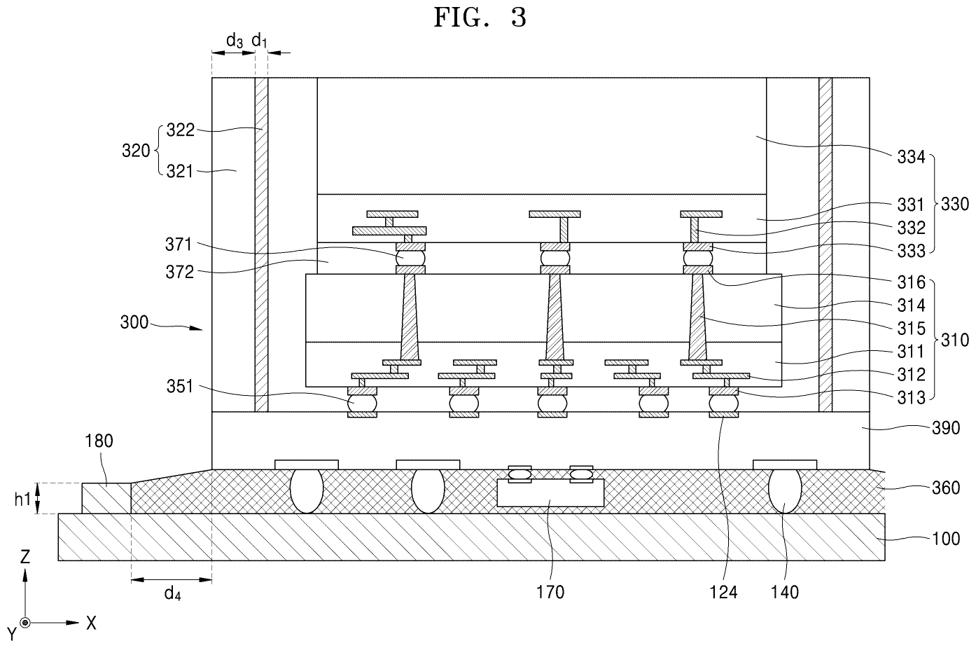

FIG. 3 is an enlarged cross-sectional view of part EX1 in FIG. 2.

Referring to FIG. 3, the second semiconductor package 300 may include the second substrate 390, the lower semiconductor chip 310, the upper semiconductor chip 330, and the molding layer 320. The second semiconductor package 300 may be mounted on the first substrate 100. In some embodiments, the second substrate 390 may be mounted on the first substrate 100 via the second bumps 140. A manual component 170 may be mounted on the lower surface of the second substrate 390. According to some embodiments, the manual component 170 may include a surface-mount device (SMD), or a capacitor or a resistor. A connection terminal of the manual component 170 may be provided on the upper surface of the manual component 170, and a conductive connecting pillar may be attached on the connection terminal of the manual component 170 for electrical connection between the manual component 170 and the second substrate 390.

For example, the connecting pillar may include a conductive material such as copper (Cu), aluminum (Al), etc.

The lower semiconductor chip 310 and the upper semiconductor chip 330 may be mounted on the second substrate 390. In some embodiments, any one of the lower semiconductor chip 310 and the upper semiconductor chip 330 may include a logic chip and the other may include a memory chip, but the embodiments are not limited thereto, that is, both the lower semiconductor chip 310 and the upper semiconductor chip 330 may include logic chips or memory chips.

The lower semiconductor chip 310 may include a first semiconductor substrate 314, a first element layer 311, first bump pads 313, and second bump pads 316. The first semiconductor substrate 314 may have an upper surface and a lower surface opposite to each other. The upper surface of the first semiconductor substrate 314 may face the upper semiconductor chip 330 and the lower surface of the first semiconductor substrate 314 may face the second substrate 390. The upper surface of the first semiconductor substrate 314 may be referred to as a non-active surface and the lower surface of the first semiconductor substrate 314 may be referred to as an active surface.

The first semiconductor substrate 314 may include silicon (Si), for example, crystalline silicon, polycrystalline silicon, or amorphous silicon. Alternatively, the first semiconductor substrate 314 may include a semiconductor element such as germanium, or a compound semiconductor such as silicon carbide (SiC), gallium arsenide (GaAs), indium arsenide (InAs), or indium phosphide (InP). In addition, the first semiconductor substrate 314 may have a silicon on insulator (SOI) structure. For example, the first semiconductor substrate 314 may include a buried oxide (BOX) layer. The first semiconductor substrate 314 may include a conductive region, for example, a well doped with impurities or a structure doped with impurities. Also, the first semiconductor substrate 314 may have various isolation structures, e.g., a shallow trench isolation (STI) structure.

The first element layer 311 may include first wiring patterns 312 that are electrically connected to a plurality of semiconductor devices formed on the first semiconductor substrate 314. The first wiring pattern 312 may include a metal wiring layer and a via plug. For example, the first wiring pattern 312 may have a multi-layered structure in which two or more metal wiring layers or two or more via plugs are alternately stacked.

According to some embodiments, the first element layer 311 may be formed on the lower surface of the first semiconductor substrate 314, that is, the active surface. The first element layer 311 may be located under the first semiconductor substrate 314. The first semiconductor substrate 314 may be spaced apart from the second substrate 390 in the vertical direction (Z-axis direction) with the first element layer 311 therebetween. The lower semiconductor chip 310 may include through-electrodes 315 passing through at least part of the first element layer 311 and the first semiconductor substrate 314.

The first bump pad 313 may be on the lower surface of the first element layer 311 and may be electrically connected to the first wiring pattern 312 in the first element layer 311. The first bump pad 313 may be electrically connected to the through-electrode 315 via the first wiring pattern 312.

The through-electrode 315 may pass through parts of the first semiconductor substrate 314 and the first element layer 311. The through-electrode 315 may extend from the first element layer 311 toward the upper surface of the first semiconductor substrate 314 in the vertical direction (Z-axis direction), and may be electrically connected to the first wiring pattern 312 provided in the first element layer 311. Therefore, the first bump pad 313 may be electrically connected to the through-electrode 315 via the first wiring pattern 312. The through-electrode 315 may have a tapered shape of which the width in the horizontal direction is reduced or increased as the level in the vertical direction increases. The through-electrode 315 may at least partially have a pillar shape. The through-electrode 315 may be a through silicon via (TSV) electrode.

The second bump pad 316 may be formed on the upper surface of the first semiconductor substrate 314, that is, the non-active surface of the first semiconductor substrate 314. The second bump pad 316 may include substantially the same material as that of the first bump pad 313.

Third bumps 351 may be in contact with the first bump pads 313. The third bumps 351 may be in contact with the first upper pads 124 on the second substrate 390. The third bump 351 may electrically connect the lower semiconductor chip 310 to the second substrate 390. Via the third bump 351, the lower semiconductor chip 310 may be provided with at least one of a control signal, a power signal, and a ground signal for operating the lower semiconductor chip 310 from the outside, provided with a data signal to be stored in the lower semiconductor chip 310 from the outside, or may provide the data stored in the lower semiconductor chip 310 to the outside. For example, the third bump 351 may include a pillar structure, a ball structure, or a solder layer.

Although not shown in FIG. 3, an underfill layer may be between the lower semiconductor chip 310 and the second substrate 390. The underfill layer may be between the lower semiconductor chip 310 and the second substrate 390 while surrounding the third bumps 351, e.g., the underfill layer may be on sidewalls of the third bumps 351. The underfill layer may include, for example, an epoxy resin formed by a capillary under-fill method. In some embodiments, the underfill layer may at least partially cover the side surface of the lower semiconductor chip 310.

The upper semiconductor chip 330 may include a second semiconductor substrate 334, a second element layer 331, and third bump pads 333. Because the upper semiconductor chip 330 may have characteristics that are the same as or similar to those of the lower semiconductor chip 310, differences from the lower semiconductor chip 310 are described below.

The second semiconductor substrate 334 may have a lower surface and an upper surface opposite to each other. The lower surface may face the lower semiconductor chip 310 and the upper surface of the second semiconductor substrate 334 may be opposite to the lower surface. The upper surface of the second semiconductor substrate 334 may be referred to as a non-active surface and the lower surface of the second semiconductor substrate 334 may be referred to as an active surface.

The second element layer 331 may include second wiring patterns 332 that are electrically connected to the plurality of semiconductor devices formed on the second semiconductor substrate 334. The second wiring pattern 332 may include a metal wiring layer and a via plug. For example, the second wiring pattern 332 may have a multi-layered structure in which two or more metal wiring layers or two or more via plugs are alternately stacked.

According to some embodiments, the second element layer 331 may be formed on the lower surface of the second semiconductor substrate 334, that is, the active surface. The second element layer 331 may be located under the second semiconductor substrate 334. The second semiconductor substrate 334 may be spaced apart from the lower semiconductor chip 310 in the vertical direction (Z-axis direction) with the second element layer 331 therebetween.

The third bump pads 333 may be on the lower surface of the second element layer 331 and may be electrically connected to the second wiring patterns 332 in the second element layer 331.

Fourth bumps 371 may be located between the lower semiconductor chip 310 and the upper semiconductor chip 330. The fourth bumps 371 may electrically connect the lower semiconductor chip 310 to the upper semiconductor chip 330.

The fourth bumps 371 may be in contact with the second bump pads 316 and the third bump pads 333. The fourth bumps 371 may electrically connect the lower semiconductor chip 310 to the upper semiconductor chip 330. The upper semiconductor chip 330 may be electrically connected to the lower semiconductor chip 310 via the fourth bumps 371 between the lower semiconductor chip 310 and the upper semiconductor chip 330. Via the fourth bumps 371, the upper semiconductor chip 330 may be provided with at least one of a control signal, a power signal, and a ground signal for operating the upper semiconductor chip 330, provided with a data signal to be stored in the upper semiconductor chip 330, or may provide data stored in the upper semiconductor chip 330 to the outside.

Consequently, the second semiconductor package 300 may have a 3D-IC structure, in which the lower semiconductor chip 310 and the upper semiconductor chip 330 are stacked in the vertical direction and are connected to each other via the through-electrode 315. However, kinds of the second semiconductor package 300 are not limited thereto, provided that the second semiconductor package 300 has a chip structure that needs to be fixed to an external substrate, e.g., the first substrate 100, via the underfill material layer 360.

In some embodiments, the molding layer 320 may be on or surround the lower semiconductor chip 310 and the upper semiconductor chip 330. The molding layer 320 may be formed on the second substrate 390 and may be on or surround the lower semiconductor chip 310 and the upper semiconductor chip 330. The molding layer 320 may include a molding member 321 and one or more dummy posts 322. The molding member 321 surrounds (e.g., is on sidewalls of) the lower semiconductor chip 310 and the upper semiconductor chip 330, and the dummy posts 322 may pass through the molding member 321 in the vertical direction (Z-axis direction).

A pair of dummy posts 322 may be positioned in the first horizontal direction (X-axis direction) and/or the second horizontal direction (Y-axis direction) with the lower and upper semiconductor chips 310 and 330 therebetween. Here, the dummy posts 322 may each have a cylindrical shape, and a diameter d₁ of each dummy post 322 may be at least 10 μm. However, shapes of the dummy posts 322 are not limited thereto and, for example, may be a hexahedral shape.

The dummy posts 322 may be spaced apart from the side wall of the molding member 321 by a certain distance. A distance d₃ between the dummy post 322 and the side wall of the molding member 321 may be about 50 μm. However, the distance d₃ between the dummy posts 322 and the side wall of the molding member 321 is not limited thereto and may be variously designed as necessary.

The one or more dummy posts 322 may be formed to be electrically insulated from one another. For example, the one or more dummy posts 322 may be electrically insulated from the lower semiconductor chip 310, the upper semiconductor chip 330, and the second bump 140. Here, the dummy posts 322 may include copper (Cu). However, one or more embodiments are not limited thereto, and the dummy posts 322 may include metal such as aluminum (Al), tungsten (W), silver (Ag), and gold (Au), or a combination thereof.

The upper surface of the dummy post 322 may be at the same level as that of the upper surface of the second semiconductor package 300. In detail, the upper surface of the dummy post 322 may be at the same level as that of the upper surfaces of the upper semiconductor chip 330 and the molding member 321. Because the upper surface of the dummy post 322 is exposed, the heat generated from the second semiconductor package 300, etc. may be discharged through the dummy posts 322. Therefore, the heat dissipation property of the semiconductor package 10 may be improved.

A semiconductor package according to the related art includes a plurality of semiconductor packages positioned side-by-side, and thus, warpage may occur due to coefficient of thermal expansion (CTE) mismatch during manufacturing processes. However, the semiconductor package 10 according to some embodiments may address the CTE mismatch because the molding layer 320 of the second semiconductor package 300 includes the dummy posts 322 occupying a certain volume. By arranging the dummy posts 322 having a different CTE from that of the molding member 321 on the molding layer 320, the CTE may be adjusted. Therefore, the semiconductor package 10 according to some embodiments may prevent warpage due to the CTE mismatch and have improved structural stability. Here, a ratio of the volume of the dummy posts 322 with respect to that of the molding member 321 may vary as desired.

In some embodiments, the dam structure 180 may protrude from the upper surface of the first substrate 100 in the vertical direction (Z-axis direction). Here, a height h₁ of the dam structure 180 in the vertical direction (Z-axis direction) may be at least 10 μm. For example, the height h₁ of the dam structure 180 in the vertical direction (Z-axis direction) may range between 10 μm and 20 μm. In some embodiments, the upper surface of the dam structure 180 may have a lower level than the lower surface of the second semiconductor package 300 in the vertical direction (Z-axis direction).

The dam structure 180 may be between the first semiconductor package 200 and the second semiconductor package 300. Here, a linear distance d₄ between the dam structure 180 and the second semiconductor package 300 in the first horizontal direction (X-axis direction) may be at least 100 μm.

The dam structure 180 may lengthily extend in the second horizontal direction (Y-axis direction) between the first semiconductor package 200 and the second semiconductor package 300. The length of the dam structure 180 in the second horizontal direction (Y-axis direction) may be equal to the lengths of the first semiconductor package 200 and the second semiconductor package 300 in the second horizontal direction (Y-axis direction) but is not limited thereto.

The dam structure 180 may be in contact with the underfill material layer 360 between the first substrate 100 and the second semiconductor package 300. For example, a side wall of the dam structure 180 may at least partially come into contact with the underfill material layer 360. Here, the underfill material of the underfill material layer 360 may be restricted from moving by the dam structure 180 and may not flow toward the first semiconductor package 200. The dam structure 180 may prevent the underfill material layer 360 from being formed between the first semiconductor package 200 and the first substrate 100.

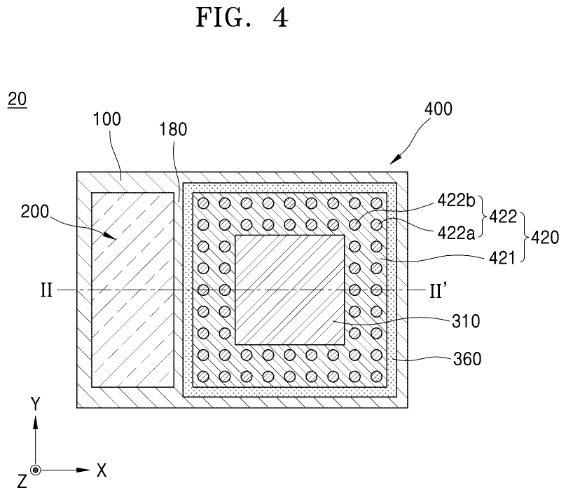

FIG. 4 is a plan view schematically showing a semiconductor package 20 according to some embodiments.

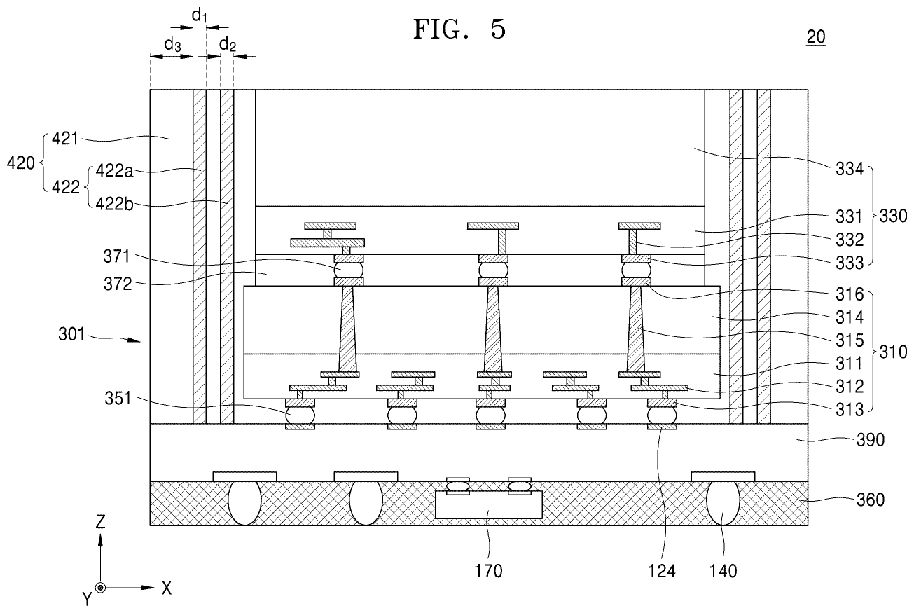

FIG. 5 is a cross-sectional view taken along line II-II′ of FIG. 4.

Referring to FIGS. 4 and 5, the semiconductor package 20 according to some embodiments may include the first substrate 100, the first semiconductor package 200, and a second semiconductor package 400. The second semiconductor package 400 may include the second substrate 390, the lower semiconductor chip 310, the upper semiconductor chip 330, and a molding layer 420. Hereinafter, the same descriptions between the semiconductor package 10 described above with reference to FIGS. 1 to 3 and the semiconductor package 20 described with reference to FIGS. 4 and 5 are omitted, and differences therebetween are described below.

In some embodiments, the molding layer 420 may be on or surround the lower semiconductor chip 310 and the upper semiconductor chip 330. The molding layer 420 may include a molding member 421 and one or more dummy posts 422. The dummy posts 422 may include first dummy posts 422a and second dummy posts 422b. The molding member 421 may be on or surround the lower semiconductor chip 310 and the upper semiconductor chip 330, and the first dummy post 422a and the second dummy post 422b may pass through the molding member 421 in the vertical direction (Z-axis direction).

The first dummy post 422a and the second dummy post 422b are spaced apart from each other and may surround or be spaced apart around or along the perimeter of the lower semiconductor chip 310 and the upper semiconductor chip 330. The first dummy posts 422a may be configured outside and the second dummy posts 422b may be configured inside, e.g., between the first dummy posts 422a and the lower semiconductor chip 310 and the upper semiconductor chip 330. For example, the first dummy posts 422a may be positioned adjacent to the side wall of the molding member 421 and the second dummy posts 422b may be positioned adjacent to the lower and upper semiconductor chips 310 and 330. The second dummy posts 422b may be surround or be spaced apart around or along the perimeter of the lower semiconductor chip 310 and the upper semiconductor chip 330, and the first dummy posts 422a may surround the second dummy posts 422b, e.g., such that the second dummy posts 422b are spaced apart around or along the perimeter of the lower semiconductor chip 310 and the upper semiconductor chip 330 with the first dummy posts 422a between the second dummy posts and the lower semiconductor chip 310 and the upper semiconductor chip 330.

The first dummy posts 422a may be spaced apart from one another in the horizontal direction (X-axis direction and/or Y-axis direction). The second dummy posts 422b may be spaced apart from one another in the horizontal direction (X-axis direction and/or Y-axis direction). The first and second dummy posts 422a and 422b may be spaced apart a certain distance from one another in the horizontal direction (X-axis direction and/or Y-axis direction). The first dummy posts 422a and the second dummy posts 422b may be spaced apart at constant intervals from one another but are not limited thereto, that is, may be configured with irregular spacing.

In FIGS. 4 and 5, a pair of first dummy posts 422a and a pair of second dummy posts 422b are positioned in the first horizontal direction (X-axis direction) and/or the second horizontal direction (Y-axis direction) with the lower and upper semiconductor chips 310 and 330 therebetween, but in some embodiments, the molding layer 420 may further include a plural pairs of dummy posts 422.

In some embodiments, the first and second dummy posts 422a and 422b may each have a cylindrical shape. However, the shapes of the first and second dummy posts 422a and 422b are not limited thereto and may each be a hexahedral shape, etc. Diameters d₁ and d₂ of the first and second dummy posts 422a and 422b may each be 10 μm or greater. The diameter d₁ of the first dummy post 422a and the second diameter d₂ of the second dummy post 422b may be equal to each other but are not limited thereto. For example, the diameter d₁ of the first dummy post 422a may be greater than the diameter d₂ of the second dummy post 422b.

The first dummy post 422a may be spaced apart a certain distance from the side wall of the molding member 421. A distance d₃ between the first dummy post 422a and the side wall of the molding member 421 may be about 50 km. However, the distance d₃ between the first dummy post 422a and the side wall of the molding member 421 is not limited thereto and may be variously designed as necessary.

The first dummy post 422a and the second dummy post 422b may be electrically insulated from each other. For example, the first dummy post 422a and the second dummy post 422b may be electrically insulated from the lower semiconductor chip 310, the upper semiconductor chip 330, the second bump 140, etc. Here, the first dummy post 422a and the second dummy post 422b may include copper (Cu). However, one or more embodiments are not limited thereto, and the first and second dummy posts 422a and 422b may include metal such as aluminum (Al), tungsten (W), silver (Ag), and gold (Au), or a combination thereof.

Upper surfaces of the first dummy post 422a and the second dummy post 422b may be at the same level as that of the second semiconductor package 300. In detail, the upper surfaces of the first and second dummy posts 422a and 422b may be at the same level as the upper surfaces of the upper semiconductor chip 330 and the molding member 421. Because the upper surfaces of the first dummy post 422a and the second dummy post 422b are exposed, the heat generated from the second semiconductor package 400, etc. may be dissipated via the first and second dummy posts 422a and 422b. Therefore, the heat dissipation property of the semiconductor package 20 in some embodiments may be improved.

According to the semiconductor package 20 in some embodiments, the molding layer 420 of the second semiconductor package 400 includes the first dummy posts 422a and the second dummy posts 422b occupying a certain volume, and thus, the CTE mismatch may be addressed. By arranging the first dummy posts 422a and the second dummy posts 422b having different CTEs from that of the molding member 421 in the molding layer 420, the CTE may be adjusted. Therefore, the semiconductor package 20 in some embodiments may prevent warpage due to the CTE mismatch and have improved structural stability. Here, a ratio of the volume of the first and second dummy posts 422a and 422b with respect to the volume of the molding member 421 may be variously designed as necessary.

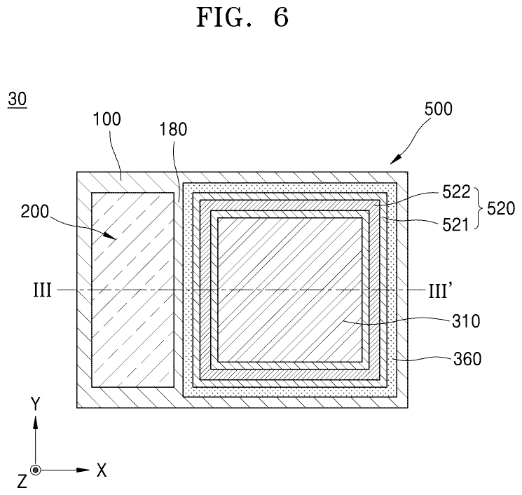

FIG. 6 is a plan view schematically showing a semiconductor package 30 according to some embodiments.

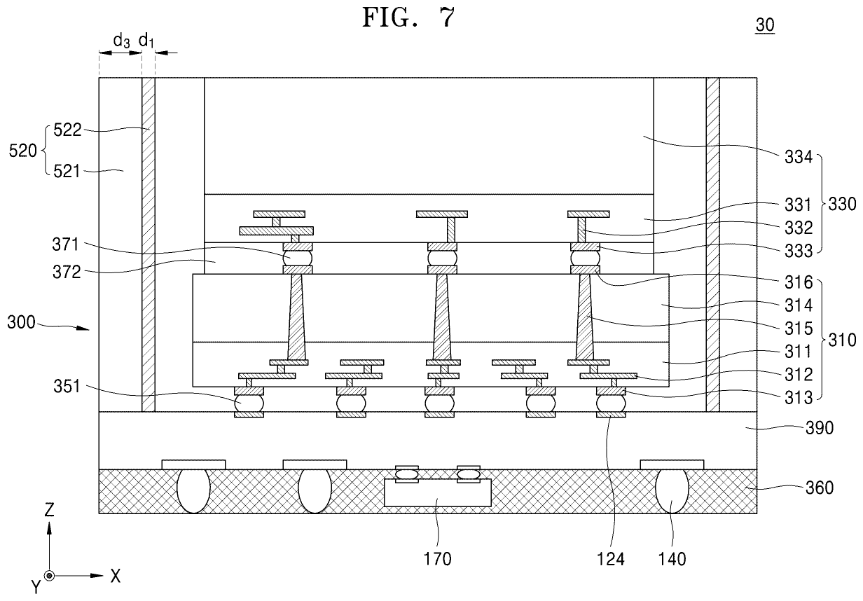

FIG. 7 is a cross-sectional view taken along line III-III′ of FIG. 6.

Referring to FIGS. 6 and 7, the semiconductor package 30 according to some embodiments may include the first substrate 100, the first semiconductor package 200, and a second semiconductor package 500. The second semiconductor package 500 may include the second substrate 390, the lower semiconductor chip 310, the upper semiconductor chip 330, and a molding layer 520. Hereinafter, the same descriptions between the semiconductor package 10 described above with reference to FIGS. 1 to 3 and the semiconductor package 30 with reference to FIGS. 6 and 7 are omitted, and differences therebetween are described below.

In some embodiments, the molding layer 520 may surround or be on the lower semiconductor chip 310 and the upper semiconductor chip 330. The molding layer 520 may include a molding member 521 and a dummy post 522. The molding member 521 surrounds or is on the lower semiconductor chip 310 and the upper semiconductor chip 330, and the dummy post 522 may pass through the molding member 521 in the vertical direction (Z-axis direction).

In some embodiments, the dummy post 522 may have an integral-type structure. The dummy post 522 may be formed in a square loop shape having an integrated structure. However, the shape of the dummy post 522 is not limited thereto, that is, the dummy post 522 may be formed in a circular loop shape having an integrated structure. Here, a width d₁ of the dummy post 522 may be at least 10 μm.

The dummy post 522 may be spaced apart from the side wall of the molding member 521 by a certain distance. The distance d₃ between the dummy post 522 and the side wall of the molding member 521 may be about 50 μm. However, the distance d₃ between the dummy post 522 and the side wall of the molding member 321 is not limited thereto and may be variously designed as necessary.

In FIGS. 6 and 7, it is shown that one integrated-type dummy post 522 surrounds or is on sidewalls of the lower and upper semiconductor chips 310 and 330, but in some embodiments, the molding layer 520 may further include a plural pairs of dummy posts 522. For example, a plurality of integrated-type dummy posts 522 may be spaced apart from one another with certain intervals therebetween. Also, the molding layer 520 may further include dummy posts having cylindrical shapes (e.g., 322 of FIG. 1) described above, as well as the integrated-type dummy post 522.

The dummy post 522 may be configured to be electrically insulated. For example, the dummy posts 522 may be electrically insulated from the lower semiconductor chip 310, the upper semiconductor chip 330, the second bump 140, etc. Here, the dummy post 522 may include copper (Cu). However, one or more embodiments are not limited thereto, and the dummy posts 322 may include metal such as aluminum (Al), tungsten (W), silver (Ag), and gold (Au), or a combination thereof.

The upper surface of the dummy post 522 may be at the same level as that of the upper surface of the second semiconductor package 300. In detail, the upper surface of the dummy post 522 may be at the same level as that of the upper surfaces of the upper semiconductor chip 330 and the molding member 521. Because the upper surface of the dummy post 522 is exposed, the heat generated from the second semiconductor package 300, etc. may be discharged through the dummy post 522. Therefore, the heat dissipation property of the semiconductor package 30 in some embodiments may be improved.

The semiconductor package 30 in some embodiments may address the CTE mismatch because the molding layer 520 of the second semiconductor package 300 includes the dummy post 522 occupying a certain volume. By arranging the dummy post 522 having a different CTE from that of the molding member 521 on the molding layer 520, the CTE may be adjusted. Therefore, the semiconductor package 30 in some embodiments may prevent warpage due to the CTE mismatch and have improved structural stability. Here, the ratio of the volume of the dummy post 522 with respect to that of the molding member 521 may be designed variously as necessary.

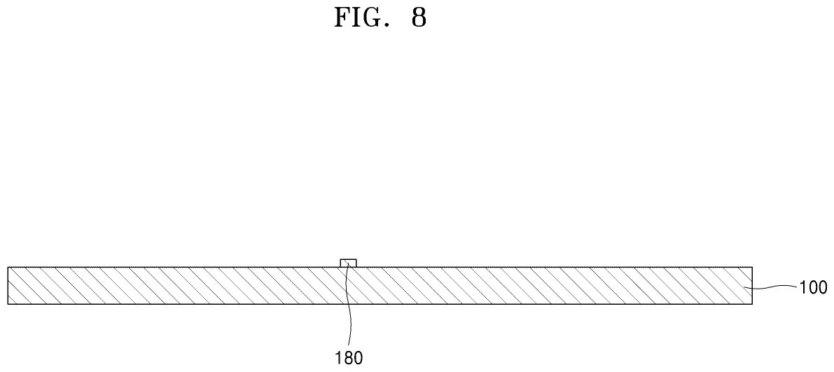

FIGS. 8 to 12 are cross-sectional views schematically illustrating a method of manufacturing the semiconductor package 10, according to some embodiments. In detail, FIGS. 8 to 12 are cross-sectional views for describing the method of manufacturing the semiconductor package 10 according to FIGS. 1 to 3, and redundant descriptions are omitted hereinafter.

Referring to FIG. 8, the first substrate 100 including the dam structure 180 protruding in the vertical direction (Z-axis direction) is prepared. Here, the first substrate 100 may include a ceramic substrate, a PCB, an organic substrate, a redistribution structure, an interposer substrate, etc.

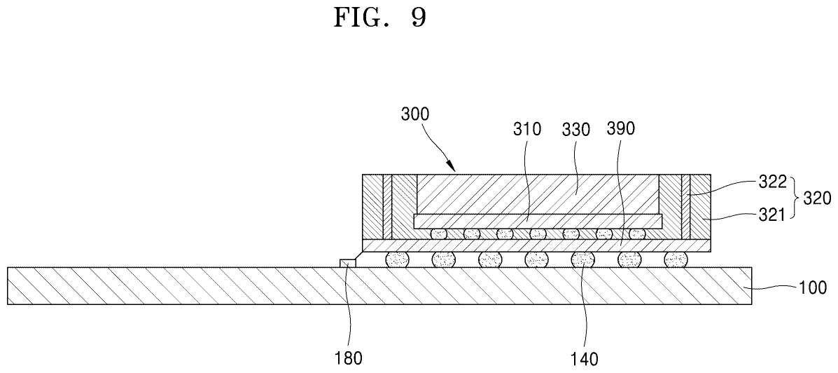

Referring to FIG. 9, the second semiconductor package 300 may be mounted on the first substrate 100. The second semiconductor package 300 may be mounted on the first substrate 100 in a flip-chip bonding method via the second bump 140.

The second semiconductor package 300 may be formed by forming the lower semiconductor chip 310, the upper semiconductor chip 330, and the dummy posts 322 on the upper surface of the second substrate 390, and covering the lower semiconductor chip 310, the upper semiconductor chip 330, and the dummy posts 322 with the molding member 321. Hereinafter, the second bump 140 is formed on the lower surface of the second substrate 390, and then may be mounted on the first substrate 100.

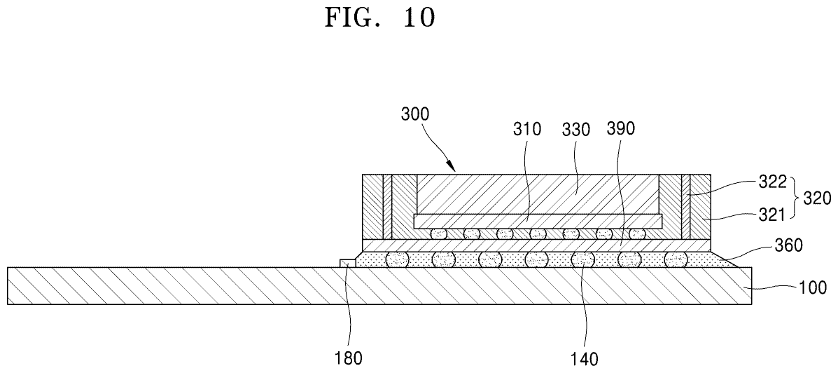

Referring to FIG. 10, the underfill material layer 360 on or surrounding the second bump 140 between the second semiconductor package 300 and the first substrate 100 may be formed. The underfill material layer 360 may include, for example, an epoxy resin formed by a capillary underfill method. Here, due to the dam structure 180, the underfill material layer 360 may not infiltrate into the opposite side of the second semiconductor package 300.

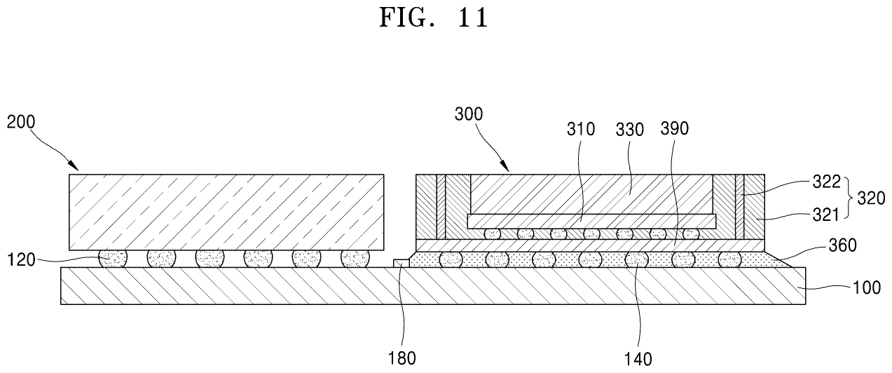

Referring to FIG. 11, the first semiconductor package 200 may be mounted on the first substrate 100. The first semiconductor package 200 may be mounted on the first substrate 100 in a flip-chip bonding method via the first bump 120. The first semiconductor package 200 and the second semiconductor package 300 may be positioned side-by-side. The first semiconductor package 200 may be spaced apart from the second semiconductor package 300 in the first horizontal direction (X-axis direction) on the first substrate 100.

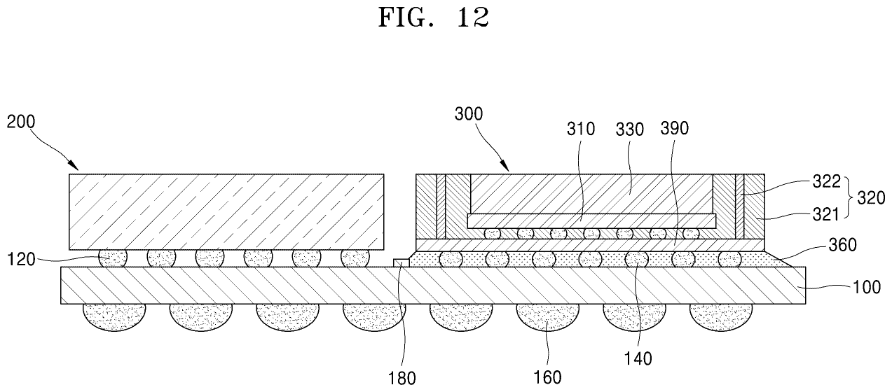

Referring to FIG. 12, the external connection terminal 160 may be on the lower surface of the first substrate 100. The external connection terminal 160 may be electrically connected to an external connection device via pads formed on the lower surface of the first substrate 100. The external connection device may include, for example, a motherboard, PCB, etc., or may include a package substrate.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first substrate;
a first semiconductor package on the first substrate and including a first semiconductor chip; and
a second semiconductor package on the first substrate spaced apart from the first semiconductor package in a horizontal direction, and including one or more semiconductor chips and a molding layer on the one or more semiconductor chips,
wherein the molding layer includes
a molding member and one or more dummy posts electrically insulated from one another and extending into the molding member in a vertical direction.

2. The semiconductor package of claim 1, wherein an upper surface of the one or more dummy posts is at a same level as an upper surface of the molding member.

3. The semiconductor package of claim 1, wherein the one or more dummy posts has a cylinder shape.

4. The semiconductor package of claim 2, wherein the one or more dummy posts has a diameter of 10 μm or greater.

5. The semiconductor package of claim 1, wherein the one or more dummy posts is along a perimeter of the one or more semiconductor chips.

6. The semiconductor package of claim 5, wherein the one or more dummy posts are spaced apart from each other at constant intervals in a horizontal direction.

7. The semiconductor package of claim 1, wherein the one or more dummy posts comprises one integrated dummy post extending in a loop around the one or more semiconductor chips.

8. The semiconductor package of claim 1, wherein the one or more dummy posts includes copper (Cu), aluminum (Al), tungsten (W), silver (Ag), gold (Au), or a combination thereof.

9. The semiconductor package of claim 1, wherein the first semiconductor package includes a memory device and the second semiconductor package includes a logic device.

10. The semiconductor package of claim 1, further comprising a dam structure protruding on the first substrate in a vertical direction and between the first semiconductor package and the second semiconductor package.

11. The semiconductor package of claim 10, further comprising
an underfill material layer between the second semiconductor package and the first substrate,
wherein a side wall of the dam structure at least partially contacts the underfill material layer.

12. The semiconductor package of claim 10, wherein a height of the dam structure in the vertical direction is 10 μm or greater.

13. A semiconductor package comprising:
a first substrate;
a first semiconductor package on the first substrate and including a first semiconductor chip; and
a second semiconductor package on the first substrate spaced apart from the first semiconductor package in a horizontal direction, and including one or more semiconductor chips and a molding layer on the one or more semiconductor chips;
an underfill material layer between the second semiconductor package and the first substrate; and
a dam structure protruding on the first substrate in a vertical direction and having a side wall at least partially contacting the underfill material layer,
wherein the molding layer includes a molding member and one or more dummy posts electrically insulated from one another and extending into the molding member in a vertical direction.

14. The semiconductor package of claim 13, wherein an upper surface of the one or more dummy posts is at a same level as an upper surface of the molding member.

15. The semiconductor package of claim 13, wherein the one or more dummy posts is along a perimeter of the one or more semiconductor chips.

16. The semiconductor package of claim 13, wherein the dam structure is between the first semiconductor package and the second semiconductor package.

17. The semiconductor package of claim 15, wherein the first semiconductor package includes a memory device and the second semiconductor package includes a logic device.

18. A semiconductor package comprising:
a first substrate;
a first semiconductor package on the first substrate and including a first semiconductor chip; and
a second semiconductor package comprising a second substrate, a lower semiconductor chip on the second substrate, an upper semiconductor chip on the lower semiconductor chip, and a molding layer on the lower semiconductor chip and the upper semiconductor chip, and on the first substrate spaced apart from the first semiconductor package in a horizontal direction;
an underfill material layer between the second semiconductor package and the first substrate; and
a dam structure protruding on the first substrate in a vertical direction and having a side wall at least partially contacting the underfill material layer,
wherein the molding layer includes
a molding member on the second substrate, and one or more dummy posts that are electrically insulated from one another and positioned along a perimeter of the upper semiconductor chip and the lower semiconductor chip extending through the molding member in a vertical direction.

19. The semiconductor package of claim 18, wherein the first semiconductor package includes a memory device and the second semiconductor package includes a logic device.

20. The semiconductor package of claim 18, wherein the one or more dummy posts comprises one integrated dummy post extending in a loop around the upper semiconductor chip and the lower semiconductor chip.
